(19) United States
(12) Patent Application Publication
(10) Pub. No.: US 2010/0244981 A1
(43) Pub. Date: Sep. 30, 2010

(54) RADIO FREQUENCY POWER DIVIDER AND COMBINER CIRCUIT

(76) Inventor: OLEKSANDR GORBACHOV, Kiev (UA)

Correspondence Address: STETINA BRUNDA GARRED & BRUCKER, 75 ENTERPRISE, SUITE 250, ALISO VIEJO, CA, 92656, US

(21) Appl. No.: 12/467,049

(22) Filed: May 15, 2009

Related U.S. Application Data
(60) Provisional application No. 61/164,774, filed on Mar. 30, 2009.

(51) Int. Cl. H03H 7/38

(52) U.S. Cl. 333/124

(57) ABSTRACT

A radio frequency (RF) power splitter circuit is disclosed. The circuit has a predefined operating frequency, and includes a first split port, a second split port, and a common port. A first inductor is connected to the first split port and the common port, and a second inductor is connected to the second split port and the common port. Additionally, there is a resonant capacitor and a compensation resistor connected in parallel across the first split port and the second split port. A parallel resonant circuit is thus defined at the predefined operating frequency.

### CROSS-REFERENCE TO RELATED APPLICATIONS

This application relates to and claims the benefit of U.S. Provisional Application No. 61/164,774, filed Mar. 20, 2009 and entitled SMALL-SIZE ON-DIE RF POWER DIVIDER-COMBINER, which is wholly incorporated by reference herein.

### STATEMENT RE: FEDERALLY SPONSORED RESEARCH/DEVELOPMENT

Not Applicable

### BACKGROUND

1. Technical Field

The present invention generally relates to radio frequency (RF) devices, and more particularly to small-size on-die RF power divider and combiner circuitry.

2. Related Art

Modern wireless communications systems utilize a variety of complex, tightly integrated RF circuits that are typically segregated into multiple chains, each processing the signal thereon differently. For example, a conventional cellular phone may utilize a single antenna for receiving a Wireless LAN (802.11x) signal as well as a Bluetooth (802.15.11) signal, but utilize a separate transceiver to down-convert the RF signal, demodulate the baseband signal, and decode the digital data represented by the baseband signal. In order for the WLAN signal to be processed independently of the Bluetooth signal, its influence must be minimized, that is, the WLAN chain must be isolated as much as possible from the Bluetooth chain.

A number of solutions have been contemplated in the art, one of which is the Wilkinson splitter or power divider-combiner. As is well known, a Wilkinson splitter includes a common port and two or more independent ports, with each port having the same impedance. In a two-way splitter operating as a power divider, a signal applied to the common port is split into two equal parts having the same phase at each of the two independent ports. The power level at the independent port is understood to be half the power level at the common port. When operating as a power combiner, the signal applied to either one of the independent ports is output at the common port with half the power level, while two in-phase signals simultaneously applied to the independent ports are summed and output at the common port with the combined power level. Ideally, the independent ports are each isolated from each other, and no signal input to one of the independent ports is output to any of the other independent ports at a predefined operating frequency. In actual implementation, however, there may be a small amount of leakage between the independent ports.

One way in which the Wilkinson divider is implemented is with quarter wavelength transmission lines that each connects the common port to the respective independent ports. The length of the transmission line is selected to be a quarter of the wavelength of the predefined operating frequency. Additionally, ballast resistors are connected between each of the independent ports, and serves to dissipate excess power and isolate one independent port from the other. If the necessary quarter wavelength transmission line cannot be realized, or if there is an unacceptably high insertion loss, an additional quarter wavelength transmission line may be added between the common port and the junction of the other transmission lines. Unequal power splits are possible with additional quarter wavelength transmission lines between the ballast resistor and the independent port, where such transmission lines have different impedances depending upon the desired split ratio.

Quarter wavelength transmission lines, however, are generally unsuitable for fabrication on semiconductor dies in low-cost applications because of its large footprint, particularly for operating frequencies below 6 GHz. Accordingly, a number of approaches to reducing the footprint of the quarter wavelength transmission line have been contemplated. One is directed to splitting the transmission line into two parts, where each has higher impedances than the single transmission line, and a capacitor that is connected in parallel to the ballast resistor. A single, higher impedance (but shorter) transmission line can also be utilized, with each port including a capacitor tied to ground. Although the total length of the quarter wavelength transmission line can be reduced, the overall footprint of the circuit remains unacceptably large for on-die fabrication, particularly with the additional capacitors. Furthermore, high transmission line impedances result in increased insertion losses.

Another approach to reducing the size of Wilkinson splitters contemplates the substitution of the quarter wavelength transmission lines with lumped capacitors and inductors. More particularly, the lumped elements are in a “Pi” arrangement in which a pair of capacitors is each tied to ground and to the opposed terminals of the inductor. Another variation includes a “T” arrangement in which the two capacitors are connected in series to the common port and the independent port, with the inductor being tied to ground and the junction between the two capacitors. The reduction in size, while significant, is insufficient for most on-die fabrication. The large values of the inductors require physical separation in order to avoid performance degradation attributable to mutual coupling, among others. Furthermore, three separate via holes are necessary to separate the grounding of each capacitor, requiring additional die real estate. Although a common via hole can be utilized, isolation between ports is reduced. Active inductors may be substituted, but additional current draw and performance degradations for digital signals with envelope variations limit its utility.

Existing power splitter circuits are deficient in a number of different respects. Accordingly, there is a need in the art for improved on-die RF power divider and combiner circuits.

### BRIEF SUMMARY

In accordance with one embodiment of the present invention, a radio frequency (RF) power splitter circuit having a predefined operating frequency is contemplated. The circuit may include a common port and a first and second split ports. Additionally, the circuit may include a first inductor connected to the first split port and the common port. There may also be a second inductor that is connected to the second split port and the common port, The circuit may further include a resonant capacitor connected in parallel to the first split port and the second split port, as well as a compensation resistor connected to the first split port and the second split port. The resonant capacitor, the compensation resistor, and the first and second inductors may define a parallel resonant circuit between the first split port and the second split port at the predefined operating frequency.

The present invention will be best understood by reference to the following detailed description when read in conjunction with the accompanying drawings.

### BRIEF DESCRIPTION OF THE DRAWINGS

These and other features and advantages of the various embodiments disclosed herein will be better understood with respect to the following description and drawings, in which:

FIG. 1 is a schematic diagram of a basic implementation of a radio frequency (RF) power splitter circuit in accordance with the present invention;

FIG. 2 is a graph illustrating the scattering parameters (S-parameters) of the basic implementation of the RF power splitter circuit shown in FIG. 1;

FIG. 3 is a schematic diagram of a first embodiment of the RF power splitter circuit including compensation capacitors coupled to separate split ports;

FIG. 4 is a schematic diagram of a second embodiment of the RF power splitter circuit with a single compensation capacitor coupled to the a common port;

FIG. 5 is a graph illustrating the S-parameters of the first and second embodiments of the RF power splitter circuit shown in FIGS. 3 and 4, respectively;

FIG. 6 is a schematic diagram of a third embodiment of the RF power splitter circuit with coupled inductors;

FIG. 7 is a schematic diagram of a fourth embodiment of the RF power splitter circuit with coupled inductors and a impedance transformation network;

FIG. 8 is a graph illustrating the S-parameters of the third embodiment of the RF power splitter circuit shown in FIG. 6; and

FIGS. 9A-G are graphs illustrating S-parameter variations resulting from component value differences, including capacitance, resistance, inductance, coupling coefficient, inductor loss, split port impedance, and common port impedance.

Common reference numerals are used throughout the drawings and the detailed description to indicate the same elements.

### DETAILED DESCRIPTION

The detailed description set forth below in connection with the appended drawings is intended as a description of the presently preferred embodiment of the invention, and is not intended to represent the only form in which the present invention may be developed or utilized. The description sets forth the functions of the invention in connection with the illustrated embodiment. It is to be understood, however, that the same or equivalent functions may be accomplished by different embodiments that are also intended to be encompassed within the scope of the invention. It is further understood that the use of relational terms such as first and second and the like are used solely to distinguish one from another entity without necessarily requiring or implying any actual such relationship or order between such entities.

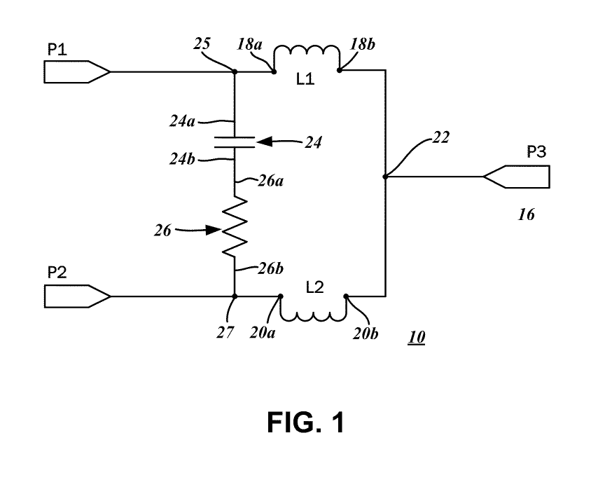

With reference to the schematic diagram of FIG. 1, a basic implementation of a radio frequency (RF) power splitter circuit 10 includes a first split port P1, a second split port P2, and a common port P3. According to this embodiment, the impedance at the common port P3 is half the impedance at the first split port P1 and the second split port P2. By way of example only and not of limitation, the impedance at the first split port P1 and the second split port P2 are set to be 50 Ohms as is conventional for standard RF components, and the impedance at the common port P3 is set to be 25 Ohms. However, it is to be understood that any other impedance of the first split port P1, the second split port P3, and the common port P3 may be substituted without departing from the present invention.

A signal applied to the common port P3 is split equally between the first split port P1 and the second split port P2. The signal at the first split port and the second split P2 are in phase with the signal at the common port P3. In this mode of operation, the power splitter circuit 10 is understood to be operating as a power divider. Where two separate RF signals are applied to the first split port P1 and the second split port P2, the power of each signal is halved and output as a combined signal at the common port P3. The phase of the combined signal is equal to the phase of each of the separate signals applied to the first split port P1 and the second split port P2. The power splitter circuit 10 is understood to be operating as a power combiner. Additionally, it is contemplated that the influence of the signal applied to the first split port P1 is minimized at the second split port P2, and vice versa.

In the various embodiments of the power splitter circuit 10, the first split port P1 is connected to a first inductor L1, and the second split port P2 is connected to a second inductor L2. As utilized herein, the term “connected” is utilized in its broadest sense, that one component is in electrical communication with another component. In this regard, the component may be directly connected to the other component, that is, there are no intermediate components interposed between, or the component may be indirectly connected to the other component, that is, there are one or more intermediate components interposed between.

With further particularity, the first inductor L1 has a first terminal 18a that is connected to the first split port P1, and the second inductor L2 has a first terminal 20a that is connected to the second split port P2. According to various embodiments, the inductance values of the first inductor L1 and the second inductor L2 are minimized to reduce insertion loss. A second terminal 18b of the first inductor L1 and a second terminal 20b of the second inductor L2 are connected to each other at a common port junction 22 and to the common port P3.

A resonance capacitor 24 is connected in parallel between the first inductor L1 and the second inductor L2 for a parallel resonance between the first split port P1 and the second split port P2. At a predefined operating frequency, the parallel resonance is understood to isolate the first split port P1 from the second split port P2. As will be described in further detail below, the capacitance value of the resonance capacitor 24 is selected with this objective. The resonance capacitor 24 includes a first terminal 24a that is connected to the first terminal 18a, and a second terminal 24b that is connected to the first terminal 20a of the second inductor L2. Because the inductive chain of the parallel resonance includes a resistive loss, a compensation resistor 26 having a first terminal 26a and a second terminal 26b is connected in series to the resonance capacitor 24. Specifically, the second terminal 24b of the resonance capacitor 24 is connected to the first terminal 26a of the compensation resistor 26. Other embodiments in which the compensation resistor 26 is connected in parallel to the resonance capacitor 24 are also contemplated, however. The first terminal 24a of the resonance capacitor 24 is connected to the first terminal 18a of the inductor L1 and to the first split port P1 at a first split port junction 25, while the second terminal 26b of the compensation resistor 26 is connected to the first terminal 20a of the second inductor L2 and the second split port P2 at a second split port junction 27.

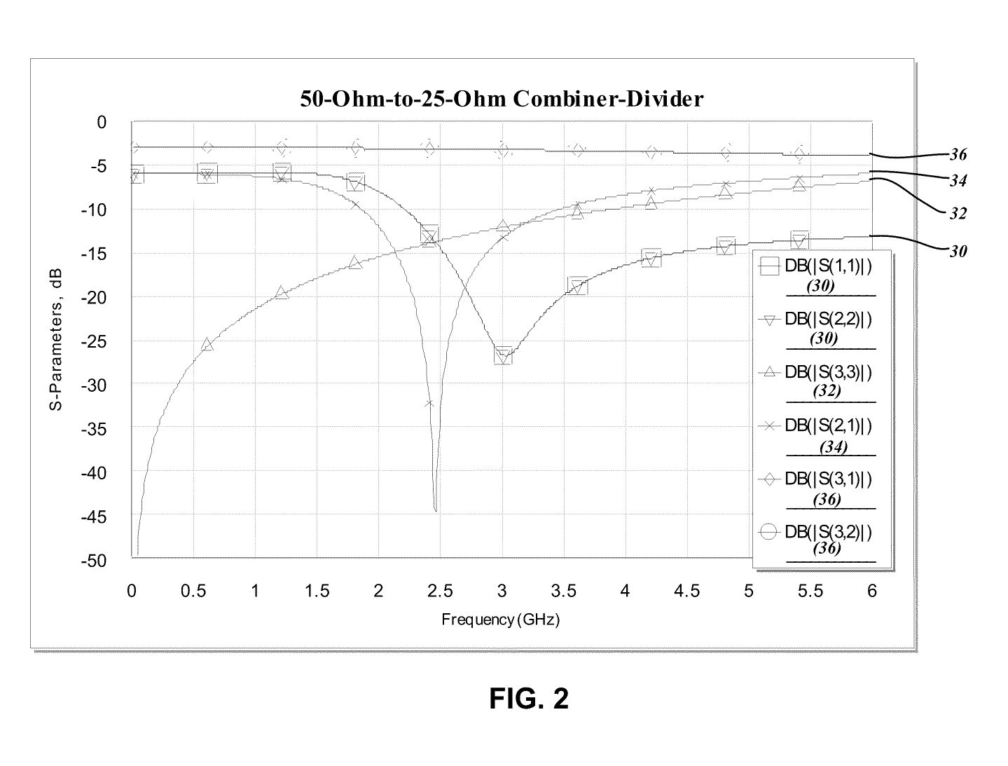

According to one embodiment of the present invention, the first inductor L1 and the second inductor L2 have an inductance value of 1.34 nH, the resonance capacitor 24 has a capacitance value of 1.55 pF, and the compensation resistor has a value of 17 Ohms. FIG. 2 shows the scattering parameters (S-parameters) of the power splitter circuit 10 based upon a simulation thereof.

Referring to the graph of FIG. 2, the scattering parameters (S-parameters), which are based upon a simulation of the power splitter circuit 10, are illustrated. The reflection coefficients for the first split port P1 (S11) and for the second split port P2 (S22) are identical and shown as plot 30. The reflection coefficient for the common port P3 (S33) is shown as plot 32. As will be recognized by those having ordinary skill in the art, the reflection coefficient is representative of the return loss at the respective ports. With a signal being applied to the second split port P2, isolation between it and the first split port P1 is represented by the transmission coefficient (S21) shown as plot 34. In the particular example shown, the power splitter circuit 10 has a predefined operating frequency of 2.45 GHz, and at that frequency, the transmission coefficient (S21) is approximately −45 dB. The transmission coefficients (S31 and S32) shown in plot 36 are representative of the attenuation of a signal applied to the common port P3 with respect to the first split port P1 and the second split port P2.

The impedance at the first split port P1, the second split port P2, and the common port P3 are understood to have an inductive component, so other embodiments of the present invention envision the use of compensation capacitors. As in the basic embodiment, the impedance at the common port P3 is a fraction, specifically, half, of the impedance at the first split port P1 and the second split port P2.

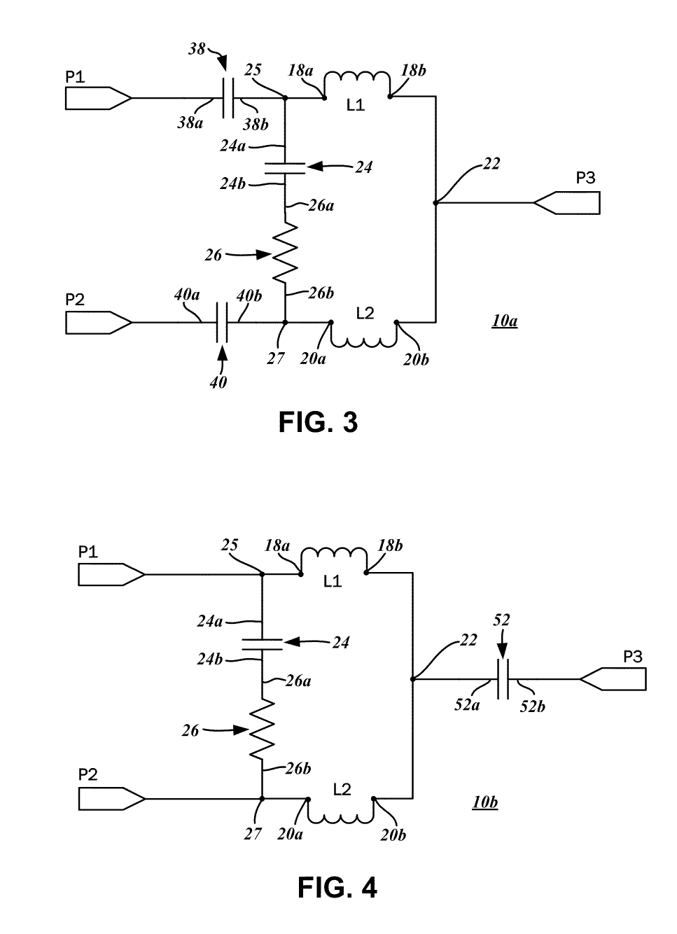

With reference to the schematic diagram FIG. 3, a first embodiment of the RF power splitter circuit 10a includes the first split port P1 that is connected to the first inductor L1. As with the previous embodiment, the first split port P1 has an impedance of 50 Ohms. In between the first split port P1 and the first split port junction 25, however, a first compensation capacitor 38 is inserted. The first compensation capacitor 38 has a first terminal 38a connected to the first split port P1, and a second terminal 38b that is connected to the first terminal 24a of the resonant capacitor 24 and the first terminal 18a of the first inductor L1. The second terminal 18b of the first inductor L1 is connected to the common port junction 22 and to the common port P3.

The second split port P2 is, in similar fashion, connected to the second inductor L2, with a second compensation capacitor 40 being interposed between the second split port P2 and the second inductor L2. The second split port P2 likewise has an impedance of 50 Ohms. The second compensation capacitor 40 has a first terminal 40a connected to the second split port P1 and a second terminal 40b that is connected to the second terminal 26b of the compensation resistor 26 and the first terminal 20a of the second inductor L2. The second terminal 20b of the second inductor L2 is also connected to the common port junction 22 and the common port P3, which has an impedance of 25 Ohms.

The first compensation capacitor 38 and the second compensation capacitor 40, as noted above, is operative to better match the impedance of the first split port P1 and the second split port P2, respectively. Furthermore, the values of the first compensation capacitor 38 and the second compensation capacitor 40 are selected to minimize the return loss at the first split port P1 and the second split port P2, respectively, at the predefined operating frequency. By way of example only and not of limitation, the first compensation capacitor 38 and the second compensation capacitor 40 are both selected to have a capacitance value of 4 pF.

The inductance values of the first inductor L1 and the second inductor L2 are selected to be equal and of minimal value in order to minimize insertion loss. In the exemplary embodiment shown in FIG. 3, the first inductor L1 and the second inductor L2 each have a value of 1.35 nH.

Generally, in the above-described configuration, the resonance capacitor 24 and the compensation resistor 26 are connected in parallel between the first inductor L1 and the second inductor L2, defining a parallel resonance. In accordance with the first embodiment, the resonance capacitor 24 has a capacitance value of 1.55 pF. At the predefined operating frequency, which in the exemplary embodiment is 2.45 GHz, the parallel resonance isolates the first split port P1 from the second split port P2. The compensation resistor 26 is connected in series with the resonance capacitor 24, with its first terminal 26a being connected to the second terminal 24b of the resonance capacitor 24. The value of the compensation resistor 256 is selected to maximize isolation between the first split port P1 and the second split port P3, and in this embodiment, has a value of 17 Ohms. One embodiment of the present invention contemplates a 20 dB isolation at the predefined operating frequency.

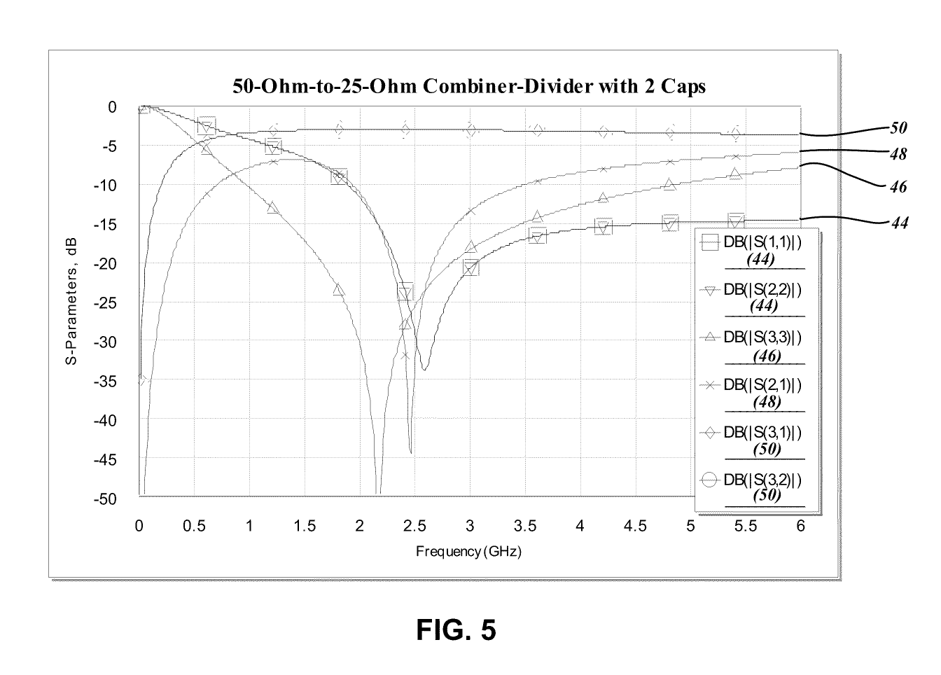

With reference to the graph of FIG. 5, simulated S-parameters for the first embodiment of the RF power splitter circuit 10a are illustrated. The reflection coefficient for the first split port P1 (S11) and the second split port P2 (S22) are again identical as shown in plot 44. The reflection coefficient for the common port P3 (S33) is shown as plot 46, which indicates that at the predefined operating frequency of 2.45 GHz, return loss is reduced to approximately −25 dB. The isolation between the first split port P1 and the second split port P2 as indicated by a plot 48 of the transmission coefficient (S21) is approximately −45 dB at the predefined operating frequency. The transmission coefficients (S31 and S32) are shown in a plot 50. As can be seen from the graph, with the introduction of the first compensation capacitor 38 and the second compensation capacitor 40 at the first split port P1 and the second split port P2, respectively, impedance matching is improved while isolation between the first split port P1 and the second split port P2 remains high.

In addition, the graph illustrates that there is a high degree of isolation between the first split port P1 and the second split port P2 at low frequencies (or close to direct current). It will be recognized by those having ordinary skill in the art that such characteristics are suitable for applications involving two different high-sensitivity receiver chains that are connected to the split ports. Specifically, leakage of the baseband signal and associated low-frequency mixing products from one receive chain is substantially reduced at the other receive chain. This exemplary application is not intended to be limiting, and the present RF power splitter circuit 10 may be variously utilized.

Referring now to the schematic diagram of FIG. 4, a second embodiment of the RF power splitter circuit 10b includes the first split port P1 that is connected to the first inductor L1, and the second split port P2 that is connected to the first inductor L2. Connected in series between the common port P3 and the common port junction 22, that is, the junction defined by the interconnected first inductor L1 and the second inductor L2, is a shared compensation capacitor 52. In further detail, the shared compensation capacitor 52 has a first terminal 52a connected to the first inductor L1 and the second inductor L2, and a second terminal 52b connected to the common port P3.

The shared compensation capacitor 52 is contemplated to better match the impedance of the first split port P1, the second split port P2, and the common port P3. As in the previously described embodiments, the first split port P1 and the second split port P2 both have an impedance of 50 Ohms, while the common port P3 has an impedance of 25 Ohms. The value of the compensation capacitor 52 is selected to minimize the return loss at each of the first split port P1, the second split port P2, and the common port P3 at the predefined operating frequency. In the illustrated exemplary embodiment, the compensation capacitor 52 has a capacitance value of 6 pF.

The resonance capacitor 24 is connected in parallel between the first inductor L1 and the second inductor L2 for a parallel resonance between the first split port P1 and the second split port P2. As with previously described embodiments, at the predefined operating frequency, the parallel resonance is understood to isolate the first split port P1 from the second split port P2. The first terminal 24a of the resonance capacitor 24 is connected to the first terminal 18a of the inductor L1, and the second terminal 24b of the resonance capacitor 24 is connected to the first terminal 26a of the compensation resistor 26. The second terminal 26b of the compensation resistor 26, in turn, is connected to the first terminal 20a of the second inductor L2 and the second split port P2 and the second split port junction 27.

By way of example, the first inductor L1 and the second inductor L2 have an inductance value of 1.35 nH, the resonance capacitor 24 has a capacitance value of 1.86 pF, and the compensation resistor has a value of 15 Ohms. It is understood that the resistive loss of the first inductor L1 and the second inductor L2 in Ohms is equal to the inductance value in nH, particularly where such components are fabricated on a semiconductor die. Furthermore, the resistive loss of the first inductor L1 and the second inductor L2 in Ohms may be twice the inductance value in nH. Accordingly, while insertion loss is reduced as compared to conventional Wilkinson power dividers noted above, isolation between the first split port P1 and the second split port P2 is degraded. In this regard, the capacitance values of the resonance capacitor 24 and the compensation capacitor 52, along with the resistance value of the compensation resistor 26 may be adjusted.

It is understood that the inductors in the RF power splitter circuit 10 occupy the most die real estate, and the greater the inductance value, the greater its size. Accordingly, the advantages of reducing the inductor value is two-fold: decreased size and decreased insertion loss. In order to maintain the same performance characteristics, however, the capacitance value of the resonance capacitor 24 may be increased. Therefore, another embodiment of the present invention contemplates that the first inductor L1 and the second inductor L2 have an inductance value of 0.8 nH (and corresponding resistance of 1.6 Ohms), while the capacitance value of the resonance capacitor 24 is 27 pF. The compensation resistor 26 is also modified to have a resistance value of 2.8 Ohms, and the shared compensation capacitor 52 may have a capacitance value of 8 pF.

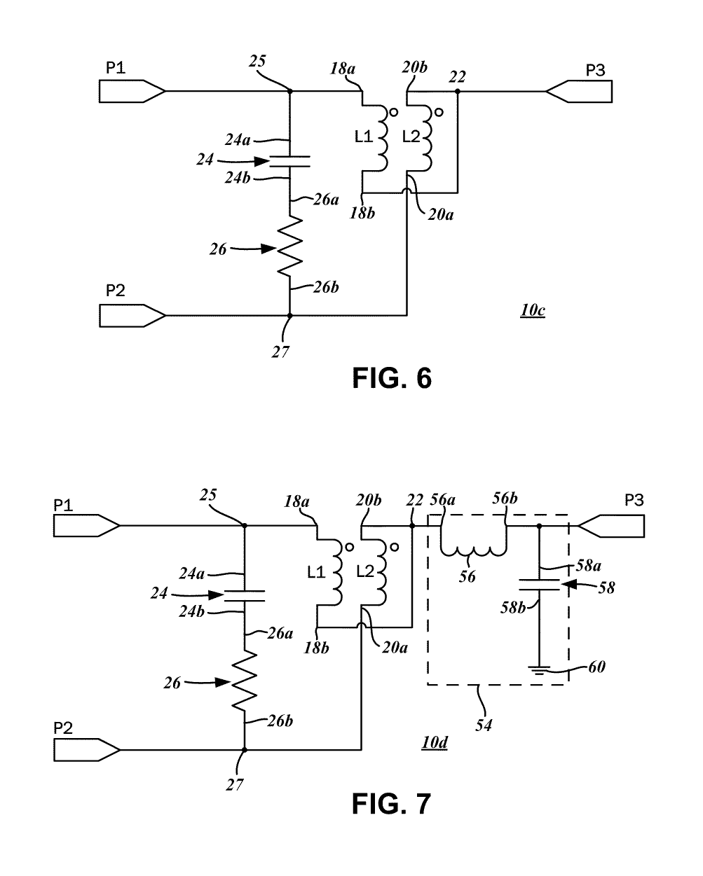

In the above-described embodiments, the first inductor L1 and the second inductor L2 are physically separated from each other to have the noted performance characteristics. However, an alternative, third embodiment of the RF power splitter circuit 10c shown in FIG. 6 contemplates coupled inductors that help reduce the overall footprint, as there is no need for physical separation.

The third embodiment of the RF power splitter circuit 10c includes the first split port P1 that is connected to the first coupled inductor L1, and the second split port P2 is connected to the second inductor L2. The first terminal 18a of the first coupled inductor L1 is connected to the first split port P1, and the second coupled inductor L2 has the first terminal 20a that is connected to the second split port P2. The impedance of the first split port P1 and the second split port P2 is contemplated to be 50 Ohms. The second terminal 18b of the first inductor 11 and the second terminal 20b of the second coupled inductor L2 are connected to each other at the common port junction 22, and to the common port P3, which is contemplated to have an impedance of 25 Ohms.

The inductance values of the first coupled inductor L1 and the second coupled inductor L2 are selected to minimize insertion loss. Furthermore, the first coupled inductor L1 and the second coupled inductor L2 are understood to have high coupling coefficients. Where the first coupled inductor L1 and the second coupled inductor L2 are fabricated on a single layer of a semiconductor die, the coupling coefficient (k) may be approximately 0.7. Alternatively, where the first coupled inductor L1 and the second coupled inductor L2 are fabricated on different layers of the semiconductor die, such as, for example, in a dual layer device, the coupling coefficient (k) may be 0.9. As indicated above, the resistive loss of the first coupled inductor L1 and the second coupled inductor L2 in Ohms is understood to be approximately twice the inductance value in nH. In one exemplary embodiment, the first coupled inductor L1 and the second coupled inductor L2 has an inductance value of 0.8 nH and a resistive loss of 1.6 Ohms.

The resonance capacitor 24 is connected in parallel between the first coupled inductor L1 and the second coupled inductor L2 for a parallel resonance between the first split port P1 and the second split port P2. At the predefined operating frequency, the parallel resonance isolates the first split port P1 from the second split port P2. In further detail, the first terminal 24a of the resonance capacitor 24 is connected to the first terminal 18a of the first inductor L1, and the first terminal 26b of the compensation resistor 26 is connected to the second terminal 24b of the resonance capacitor 24. The second terminal 26b of the compensation resistor 26 is connected to the first terminal 20a of the second coupled inductor L2 and the second split port P2 and the second split port junction 27. According to one exemplary embodiment, the resonance capacitor 24 has a capacitance value of 1.6 pF, and the compensation resistor 26 has a resistance value of 16 Ohms.

As described previously, the impedance at the first split port P1 and the second split port P2 are understood to be twice that of the common port P3. With reference to the schematic diagram of FIG. 7, a fourth embodiment of the RF power splitter circuit 10d contemplates the common port P3 having the same impedance as the first split port P1 and the second split port P2 at the predefined operating frequency. For example, each of the ports are understood to have a 50 Ohm impedance. In particular, the RF power splitter circuit 10d has an impedance transformation network 54 connected in series between the common port junction 22 of the first coupled inductor L1 and the second coupled inductor L2 and the common port P3. The common port junction 22, however, has an impedance value half that of the first split port P1 and the second split port P2. In this regard, the impedance transformation network 54 transforms the lower impedance at the common port junction 22, which is 25 Ohms, to the higher impedance of 50 Ohms at the common port P3 as indicated above.

In further detail, the impedance transformation network 54 includes a transforming inductor 56 and a transforming capacitor 58. The transforming inductor 56 has a first terminal 56a connected to the common port junction 22, and a second terminal 56b connected to the transforming capacitor 58 and the common port P3. The transforming capacitor 58 has a first terminal 58a connected to the transforming inductor 56, and a second terminal 58b connected to ground 60. In the exemplary embodiment shown, the transforming inductor 56 has an inductance value of 1.55 nH, and the transforming capacitor 58 has an inductance value of 1.25 pF.

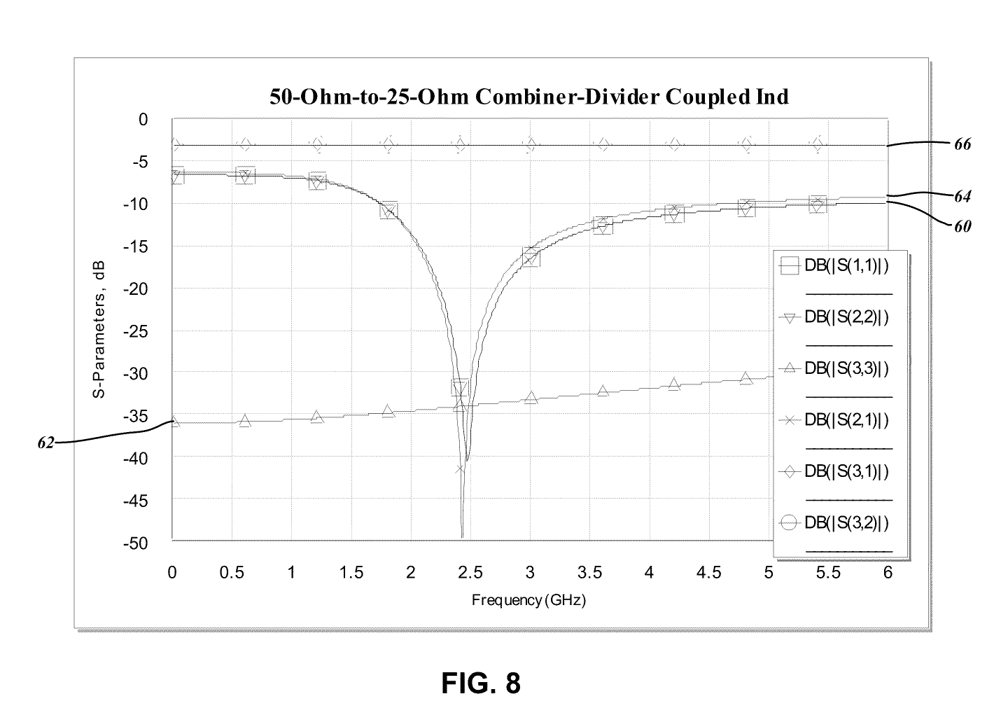

Referring now to the graph of FIG. 8, simulated S-parameters for the third embodiment of the RF power splitter circuit 10c are shown. The reflection coefficient for the first split port P1 (S11) and the second split port P2 (S22) are identical as shown in plot 44. The reflection coefficient for the common port P3 (S33) is shown as plot 60. This indicates that at the predefined operating frequency of 2.45 GHz, return loss is approximately −35 dB. The isolation between the first split port P1 and the second split port P2 is shown in plot 64 representing (S21), which is more than −50 dB at the predefined operating frequency of 2.45 GHz. The transmission coefficients (S31 and S32) are shown in a plot 66, which remains constant across the depicted frequency range. The S-parameters for the fourth embodiment of the RF power splitter circuit 10d are understood to be substantially similar to the S-parameters for the third embodiment 10c, except that the reflection coefficient of the common port P3 (S33) is closer to the reflection coefficient for the first split port P1 (S11) and the second split port P2 (S22). In this regard, the performance of the fourth embodiment 10d resembles that of an ideal Wilkinson divider-combiner comprised of quarter wavelength transmission line elements.

In accordance with the present invention, multiple circuits for different predefined operating frequencies are contemplated. As a basic design procedure, the values of the inductors, including the first inductor L1 and the second inductor L2 are selected and fixed. Thereafter, the value of the resonant capacitor 24 is selected to achieve a resonant circuit at the predefined operating frequency. The compensation resistor 26 is adjusted to achieve the maximum isolation between the first split port P1 and the second split port P2 at the predefined operating frequency. Those having ordinary skill in the art, based upon the present disclosure, will be able to determine optimal circuit parameters, in particular, by tuning the capacitance and resistance values of the resonant capacitor 24 and the compensation resistor 26, respectively, over one or more iterations. Such optimal circuit parameters are understood to achieve near-perfect matching amongst all of the ports P1, P2, and P3.

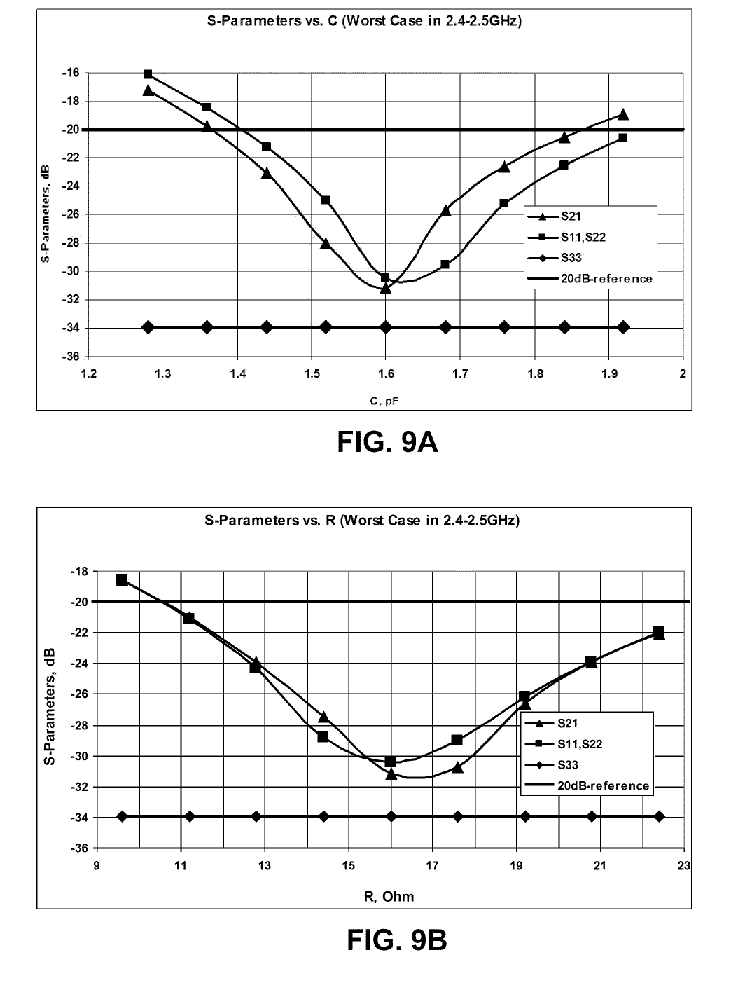

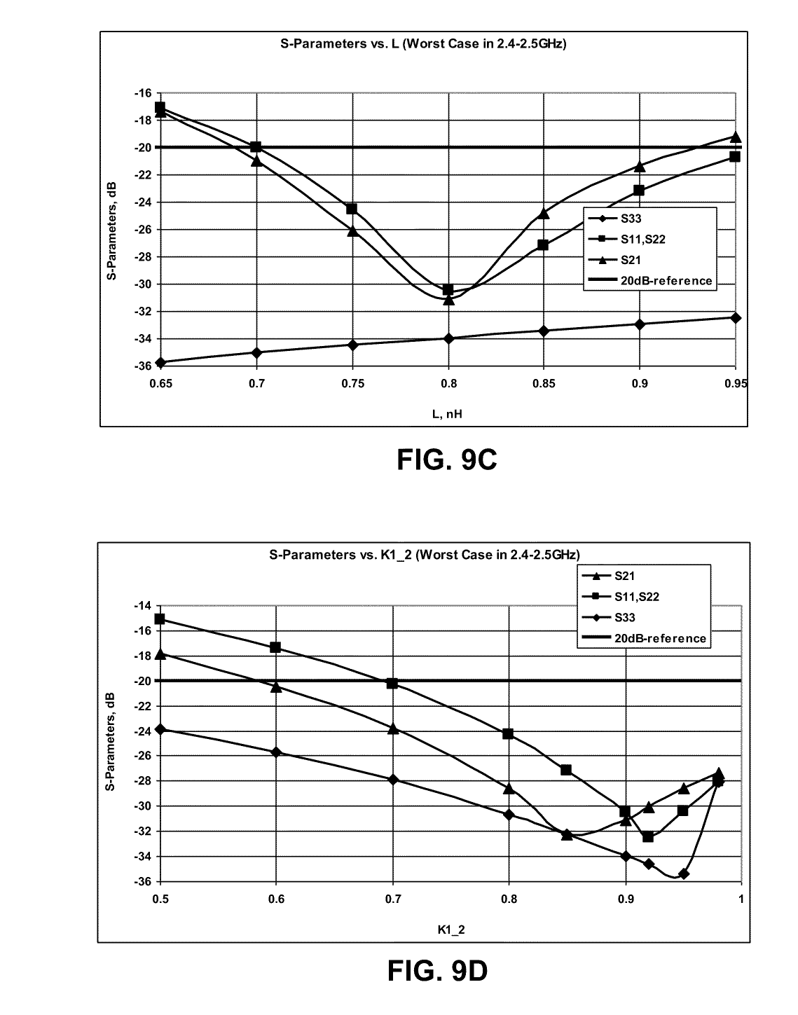

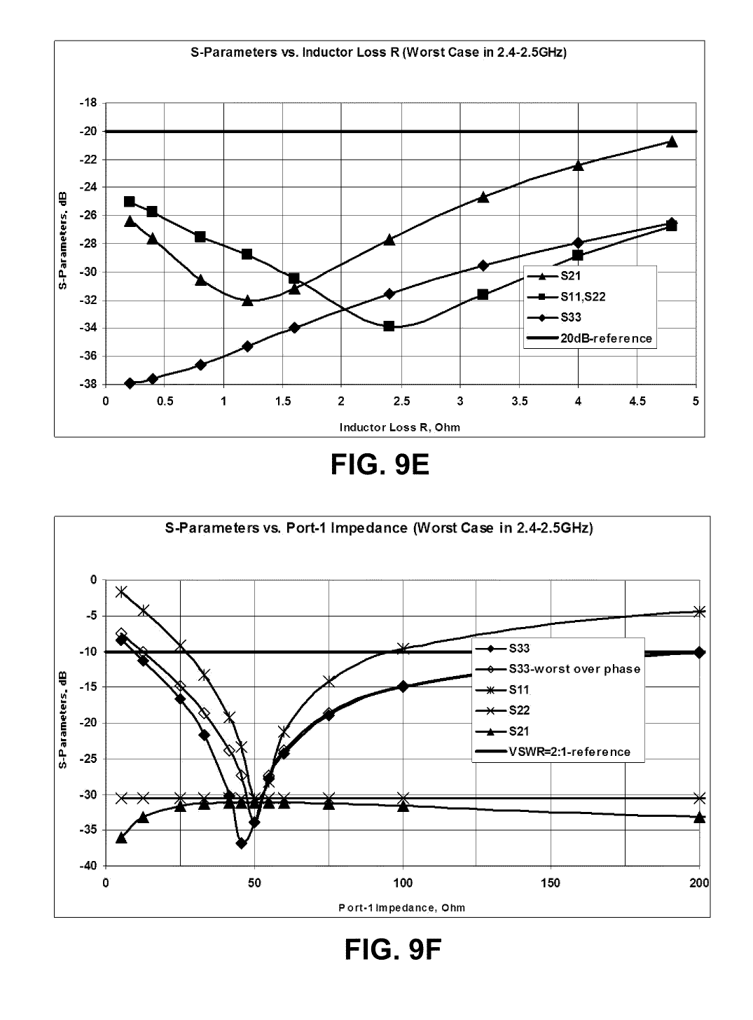

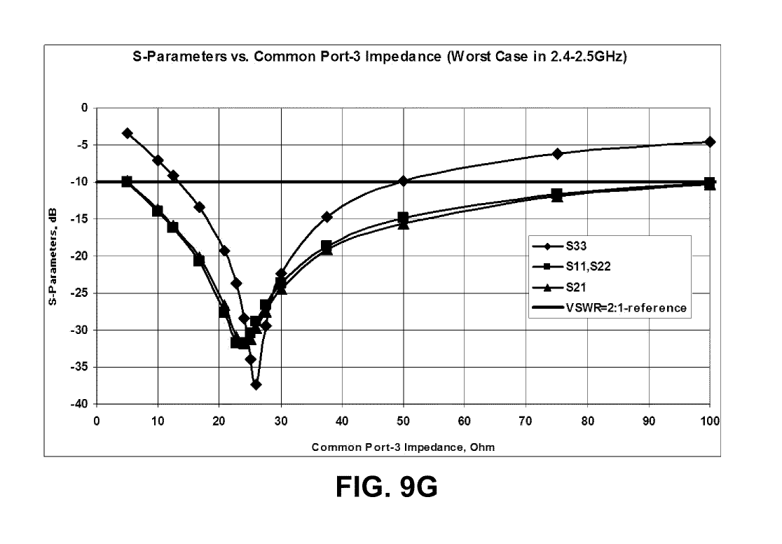

It will be appreciated that the components of the RF power splitter circuit 10 may have varying tolerances with respect to the nominal values that may cause shifts in its performance characteristics. As indicated above, some embodiments of the present invention contemplate the fabrication of the RF power splitter circuit 10 on a single semiconductor die, along with other circuits such as power amplifiers, low noise amplifiers, and the like. The die may be fabricated from a silicon substrate, a gallium arsenide substrate, or any other suitable semiconductor material. As will be described in further detail below, such semiconductor fabrication processes have associated tolerances that vary for each component. The graphs in FIGS. 9A-G illustrate the effects on the S-parameters that such variations may cause.

With reference to the graph of FIG. 9A, the variations in the transmission coefficients (S21) and the reflection coefficients (S11, S22, and S33) for variations in capacitance value for the predefined operating frequency of 2.4 to 2.45 GHz are shown. Conventional semiconductor fabrication processes in which the geometric dimensions are fixed typically have a +/−15% variation with respect to capacitance values from one wafer lot to another, so for a nominal value of 1.6 pF, the worst-case S-parameter is −20 dB.

The graph of FIG. 9B illustrates the variations in the transmission coefficients (S21) and the reflection coefficients (S11, S22, and S33) for variations in resistance value for the predefined operating frequency of 2.4 to 2.45 GHz. It is understood that conventional semiconductor fabrication processes with fixed geometric dimensions typically have a +/−40% variation in resistance from one wafer lot to another. Accordingly, with a nominal value of 16 Ohms, the worst case S-parameter is −20 dB.

The graph of FIG. 9C illustrates the variations in the transmission coefficients (S21) and the reflection coefficients (S11, S22, and S33) for variations in inductance value for the predefined operating frequency of 2.4 to 2.45 GHz. Conventional semiconductor fabrication processes with fixed geometric dimensions typically have a +/−5% variation in inductance from one wafer lot to another. Thus, with a nominal value of 0.8 nH, the worst case S-parameter is −25 dB.

The graph of FIG. 9D illustrates the variations in the transmission coefficients (S21) and the reflection coefficients (S11, S22, and S33) for variations in coupling coefficient values for the predefined operating frequency of 2.4 to 2.45 GHz. It is understood that conventional semiconductor fabrication processes with fixed geometric dimensions typically have a +/−5% variation in coupling coefficients from one wafer lot to another. Accordingly, for a nominal k value of 0.9, the worst case S-parameter is −25 dB.

The graph of FIG. 9E illustrates the variations in the transmission coefficients (S21) and the reflection coefficients (S11, S22, and S33) for variations in inductor loss values for the predefined operating frequency of 2.4 to 2.45 GHz. Varying between 2 Ohms and 4.8 Ohms, the inductor losses affect the S-parameters to be at least below −20 dB in the worst case.

The graph of FIGS. 9F and 9G illustrate the variations in transmission coefficients (S21) and the reflection coefficients (S11, S22, and S33) for variations in impedance at the first split port P1 and the common port P2, respectively. With a nominal value of 50 Ohms, even over a wide variation, the isolation between the first split port P1 and the second split port P2 remain high. Additionally, the matching conditions at the common port P3 are better than at the split ports P1 or P2.

The particulars shown herein are by way of example and for purposes of illustrative discussion of the embodiments of the present invention only and are presented in the cause of providing what is believed to be the most useful and readily understood description of the principles and conceptual aspects of the present invention. In this regard, no attempt is made to show details of the present invention with more particularity than is necessary for the fundamental understanding of the present invention, the description taken with the drawings making apparent to those skilled in the art how the several forms of the present invention may be embodied in practice.

What is claimed is:

1. A radio frequency (RF) power splitter circuit with a predefined operating frequency, the circuit comprising:
a common port;
a first split port;
a second split port;
a first circuit element connected to the first split port and the common port;
a second circuit element connected to the second split port and the common port;
a resonant circuit element connected in parallel to the first split port and the second split port, the resonant element defining a parallel resonance in combination with a respective one of the first and second circuit elements at the predefined operating frequency with a signal on a corresponding one of the first and second split ports.

2. The power splitter circuit of claim 1, wherein an impedance of the common port is a fraction of the impedance of the first split port and the second split port.

3. The power splitter circuit of claim 1, wherein the signal applied to the common port is output at the first split port and the second split port with substantially equal phase and power.

4. The power splitter circuit of claim 1, wherein a first signal applied to the first split port and a second signal applied to the second split port is output as a combined signal at the common port, the combined signal being equal in phase with the first signal and the second signal, and half the power of the first signal and the second signal.

5. A radio frequency (RF) power splitter circuit having a predefined operating frequency, the circuit comprising:
a common port;
first and second split ports;
a first inductor connected to the first split port and the common port;
a second inductor connected to the second split port and the common port;
a resonant capacitor connected in parallel to the first split port and the second split port; and
a compensation resistor connected to the first split port and the second split port;
wherein the resonant capacitor, the compensation resistor, and the first and second inductors define a parallel resonant circuit between the first split port and the second split port at the predefined operating frequency.

6. The power splitter circuit of claim 5, wherein an impedance of the common port is a fraction of the impedance of the first split port and the second split port.

7. The power splitter circuit of claim 6, wherein the impedance of the common port is half the impedance of the first split port and the second split port.

8. The power splitter circuit of claim 6, wherein the first inductor and the second inductor have equal values each selected to minimize insertion loss.

9. The power splitter circuit of claim 5, wherein the signal applied to the common port is output at the first split port and the second split port with substantially equal phase and power.

10. The power splitter circuit of claim 5, wherein a first signal applied to the first split port and a second signal applied to the second split port is output as a combined signal at the common port, the combined signal being equal in phase with the first signal and the second signal, and half the power of the first signal and the second signal.

11. The power splitter circuit of claim 5, wherein the compensation resistor is connected in series with the resonant capacitor.

12. The power splitter circuit of claim 5, wherein the compensation resistor is connected in parallel with the resonant capacitor.

13. The power splitter circuit of claim 5, wherein the compensation resistor has a value selected to substantially maximize isolation between the first split port and the second split port at the predefined operating frequency.

14. The power splitter circuit of claim 5, wherein the isolation between the first split port and the second split port at the predefined operating frequency is greater than 20 decibels (dB).

15. The power splitter circuit of claim 5, wherein the first and second inductors, the resonant capacitor, and the compensation resistor are fabricated on a single semiconductor die.

16. The power splitter circuit of claim 5, further comprising:
a first compensation capacitor connected to the first split port and in series with the first inductor; and
a second compensation capacitor connected to the second split port and in series with the second inductor.

17. The power splitter circuit of claim 16, wherein the first compensation capacitor and the second compensation capacitor have values selected to substantially minimize return loss at the respective one of the first port and the second split port at the predefined operating frequency.

18. The power splitter circuit of claim 5, further comprising:
a first compensation capacitor connected to the common port and in series with the first inductor and the second inductor.

19. The power splitter circuit of claim 18, wherein the first compensation capacitor has a value selected to substantially minimize return loss at each of the first and second split ports and the common port at the predefined operating frequency.

20. The power splitter circuit of claim 5, wherein the first inductor and the second inductor are coupled.

21. The power splitter circuit of claim 20, wherein the first and second inductors are both fabricated on a single layer of a semiconductor die.

22. The power splitter circuit of claim 21, wherein a coupling coefficient of the coupled first inductor and the second inductor is approximately 0.7.

23. The power splitter circuit of claim 20, wherein:
the first inductor is fabricated in a first layer of a semiconductor die; and
the second inductor is fabricated on a second layer of the semiconductor die different from the first layer.

24. The power splitter circuit of claim 23, wherein a coupling coefficient of the coupled first inductor and the second inductor is approximately 0.9.

25. The power splitter circuit of claim 5, further comprising:
an impedance transformation network interposed between the common port and a first junction defined by the interconnected first and second inductors, the impedance of the common port being substantially equivalent to the impedance of the first split port and the second split port.

26. The power splitter circuit of claim 25, wherein an impedance at the first junction is a fraction of the impedance of the first split port and the second split port.

27. The power splitter circuit of claim 25 wherein the impedance at the first junction is half the impedance of the first split port and the second split port.
